(19) United States
(12) Patent Application Publication
(10) Pub. No.: US 2011/0095810 A1
(43) Pub. Date: Apr. 28, 2011

(54) Linkage apparatus of AC two-wire solid-state switches

(76) Inventor: Tianlu Weng, Shanghai (CN)

(21) Appl. No.: 12/595,516

(22) PCT Filed: Apr. 10, 2008
(86) PCT No.: PCT/CN08/00723

§ 371 Date: Oct. 26, 2010

(30) Foreign Application Priority Data
Jun. 28, 2007 (CN) 200710042900.2

(51) Int. Cl. H03K 17/74

(52) U.S. Cl. 327/493

(57) ABSTRACT

This invention is based on the contents of the U.S. Pat. No. 5,831,349 and Chinese Invention Patent ZL94112284.0, ZL94114032.6 as their follow-up invention. The invention involves the technical schemes of several linkage apparatuses of AC two-wire solid-state switches. All of the AC two-wire solid-state switches of the linkage apparatuses must be the non-contact ON-OFF in the main circuits of the AC two-wire solid-state switches of the said three patents. This invention is intended to combine several or multiple the AC two-wire solid-state switches into linkage apparatus so that all of the said switches have consistently-combined ON-OFF actions, so that the application range of the AC two-wire solid-state switches is expanded from the single-phase circuit to three-phase circuit, from the low-voltage power grid to the high-voltage power grid.

### BACKGROUND OF THE INVENTION

This invention is based on the contents of Chinese Invention Patent ZL94112284.0, ZL94114032.6 and the U.S. Pat. No. 5,831,349 as their follow-up invention.

This invention involves the technical schemes of several linkage apparatuses of AC two-wire solid-state switches. All of the AC two-wire solid-state switches of the linkage apparatuses must be the non-contact ON-OFF in the main circuits of the AC two-wire solid-state switches of the said three patents. In other words, the AC two-wire solid-state switches in this specification specially refers to the AC two-wire solid-state switches of the said three patents which used the non-contact ON-OFF in main circuit.

At present, no prior art of the linkage apparatus of AC two-wire solid-state switches exists. Please refer to the said three patents' documents for detailed background technology of the AC two-wire solid-state switches.

### SUMMARY OF THE INVENTION

This invention is intended to combine several or multiple the AC two-wire solid-state switches into linkage apparatus so that all of the said switches have consistently-combined ON-OFF actions, so that the application range of the AC two-wire solid-state switches is expanded from the single-phase circuit to three-phase circuit, from the low-voltage power grid to the high-voltage power grid.

As a AC two-wire solid-state switch (hereafter referred to as “unit”) has only two external terminals, the linkage that is combined by multi-units can be classified into following three types according to their basic structures: linkage with multi-units connected in series to increase the working voltage, linkage with multi-units connected in parallel to increase working current, and three-phase linkage apparatus. The linkage with multi-units connected in parallel will not be included in this invention, because the corresponding external terminals of the units are equipotential, the ON-OFF control signal can be transmitted directly between the units need not any isolation, so its structure is relatively simple. The invention therefore will only involve three-phase linkage apparatus and linkage with multi-units connected in series.

In this invention, all units in the linkage apparatus can be classified into two kinds: a sole unit which sends out the ON-OFF control signal initially on its own (hereafter referred to as the mastering unit) and the other units which accept the ON-OFF control signal (hereafter referred to as the controlled unit). The mastering unit can be independent operation on the single-phase AC circuit and have all of the control functions of the linkage apparatus; while the controlled units should complete the ON or OFF action after receiving the ON-OFF control signal.

### BRIEF DESCRIPTION OF THE DRAWINGS

FIG. 1 shows the unit connecting circuit diagram of a preferred embodiment of the three-phase linkage apparatus of this invention.

FIG. 2 to FIG. 4 shows the unit connecting circuit diagrams of three preferred embodiments of the linkage apparatus with multi-units connected in series of this invention.

FIG. 5 to FIG. 6 shows the simplified unit connecting circuit diagram of two preferred embodiments of the three-phase high-voltage multi-units linkage apparatus of this invention.

### DETAILED DESCRIPTION

The invention will be detailed description with reference to the drawings and the embodiments as shown in the following:

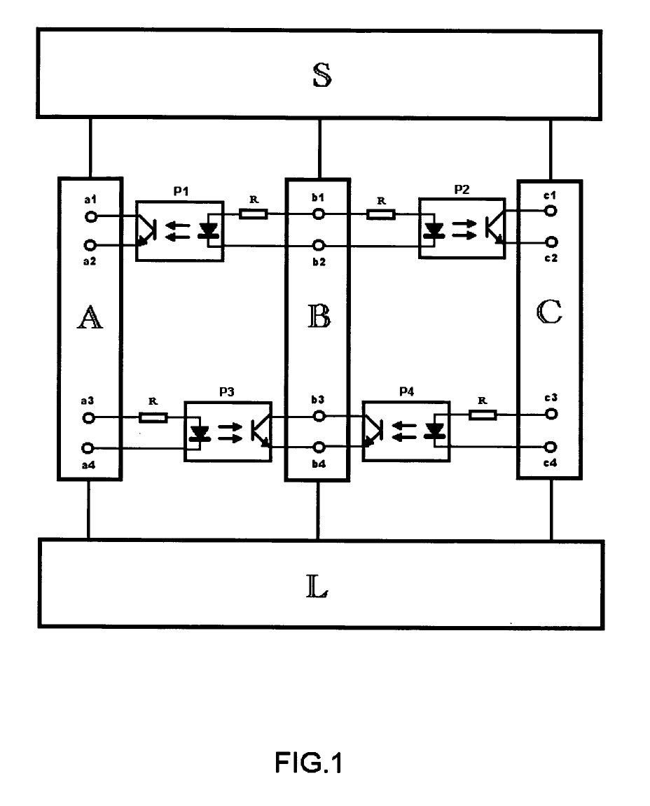

In FIG. 1, A, B, and C are the three units, P1, P2, P3 and P4 are the four photocouplers. The three-phase linkage apparatus is mainly composed of the said three units and four photocouplers, wherein, B is the mastering unit, A and C are the controlled units. In the circuit diagram of FIG. 1, S is the three-phase power supply, while L is the three-phase load. The six external terminals of the three units are connected to the three-phase power supply and the three-phase load respectively. In FIG. 1, b2 is the common reference node of the internal control circuit of the mastering unit B, b1 is the output terminal of the internal control circuit of the mastering unit B. When there are output signal in the internal control circuit of the mastering unit B, the main circuit bidirectional switching (MCBS) module in the mastering unit B is ON, that is, the mastering unit B is ON, otherwise, the MCBS module in the mastering unit B is OFF, or the mastering unit B is OFF. The mastering unit B also provides the short-circuit protection function. When it happens short-circuit fault in the external circuit of the mastering unit B, the short-circuit fault output signal on the secondary winding of the current mutual inductor via the bridge rectifying circuit enters into the short-circuit fault signal input terminal of the control circuit in the mastering unit B, result in the output signal of the internal control circuit disappears and the MCBS module is OFF, that is, the mastering unit B is from ON into OFF. In FIG. 1, b4 is the short-circuit fault signal input terminal of the internal control circuit of the mastering unit B, while b3 is a suitable positive level node as compared with the common reference node b2. In FIG. 1, a4 is the common reference node of the internal control circuit of the controlled unit A, a3 is the short-circuit fault signal output terminal on the divider which is connected to the secondary winding of the current mutual inductor via the bridge rectifying circuit in the controlled unit A; when it happens the short-circuit fault in the external circuit of the controlled unit A, this output terminal should have enough level short-circuit fault output signal; a1 is a suitable positive level node as compared with the common reference node a4, a2 is the ON-OFF signal input terminal of the internal control circuit of the controlled unit A, when this terminal gets the suitable level signal, the MCBS module in the controlled unit A is ON, that is, the controlled unit A is ON, otherwise, the MCBS module in the controlled unit A is OFF, that is, the controlled unit A is OFF. In FIG. 1, c4 is the common reference node of the internal control circuit of the controlled unit C, c3 is the short-circuit fault signal output terminal on the divider which is connected to the secondary winding of the current mutual inductor via the bridge rectifying circuit in the controlled unit C, when it happens the short-circuit fault in the external circuit of the controlled unit C, this output terminal should have enough level short-circuit fault output signal; c1 is a suitable positive level node as compared with the common reference node c4, c2 is the ON-OFF signal input terminal of the internal control circuit of the controlled unit C, when this terminal gets the suitable level signal, the MCBS module in the controlled unit C is ON, that is, the controlled unit C is ON, otherwise, the MCBS module in the controlled unit C is OFF, that is, the controlled unit C is OFF.

As for the embodiment of FIG. 1, b1 and b2 are connected respectively to the light emitting diodes (LEDs) in the photocouplers P1 and P2 though current-limiting resistor R, while the terminal a1 and a2 and the terminal c1 and c2 are connected respectively to the photoconductive transistors in the photocouplers P1 and P2, so when the internal control circuit of the mastering unit B has the output signal and the mastering unit B is ON, the output signal of the internal control circuit of the mastering unit B on b1 and b2 causes the LEDs in the photocouplers P1 and P2 lightened and the photoconductive transistors in the photocouplers P1 and P2 present a low resistance state, and the suitable positive level on a1 and c1 can reach a2 and c2 through their respective photoconductive transistors, so that the ON-OFF signal input terminals (a2 and c2) of the internal control circuits of controlled units A and C can get a suitable level signal, and the MCBS modules of controlled units A and C are ON, that is, the controlled units A and C are ON. Otherwise, when there is no output signal in the internal control circuit of mastering unit B and the mastering unit B is OFF, the LEDs in photocoupler P1 and P2 can not lighten, and the photoconductive transistors in photocoupler P1 and P2 present a high resistance state, and the suitable positive level on a1 and c1 can not reach a2 and c2 through their respective photoconductive transistor, so that the ON-OFF signal input terminals of the internal control circuits of controlled units A and C can not get the signal, and the MCBS modules in the controlled units A and C are OFF, that is, the controlled units A and C are OFF. Since via the signal transmissions of the photocouplers P1 and P2, the three units A, B and C can have consistently-combined ON-OFF actions and thus complete the linkage of the three-phase units.

As for the embodiment in FIG. 1, it has short-circuit protection function apart from the three-phase units linkage function. The embodiment can also act as the three-phase solid-state short-circuit protector, or three-phase solid-state breaker, in other words, when the short-circuit fault happens on the external circuits of any of the three units, the three units A, B and C can have consistently-combined OFF actions. As the mastering unit B itself has short-circuit protection function, when the short-circuit fault happens in the external circuit of the mastering unit B, it can OFF itself, and can result in the units A and C are OFF through the above said ON-OFF linkage function. Terminals a3 and a4, terminals c3 and c4 are connected respectively to the LEDs in the photocouplers P3 and P4 though the current-limiting resistor R, when the short-circuit fault happens in the external circuits of unit A and/or unit C, terminals a3 and/or c3 have enough level the short-circuit fault output signal, so that the LEDs in the photocouplers P3 and/or P4 lightened, and the photoconductive transistors in the photocouplers P3 and/or P4 presents a low resistance state; and then the suitable positive level on the terminal b3 can reach the short-circuit fault signal input terminal b4 in the mastering unit B through the photoconductive transistors in the photocouplers P3 and or P4, so that the MCBS module in mastering unit B is from cut-in to cut-off and the mastering unit B is OFF, and also the controlled units A and C are OFF at the same time through the ON-OFF linkage function of the mastering unit B to the controlled units A and C. Thus it can be seen, as for the embodiment in FIG. 1, when the short-circuit fault happens in the external circuit of any of the three units A, B and C, the three units A, B and C can have consistently-combined OFF actions, thus it completes the three-phase solid-state short-circuit protection function.

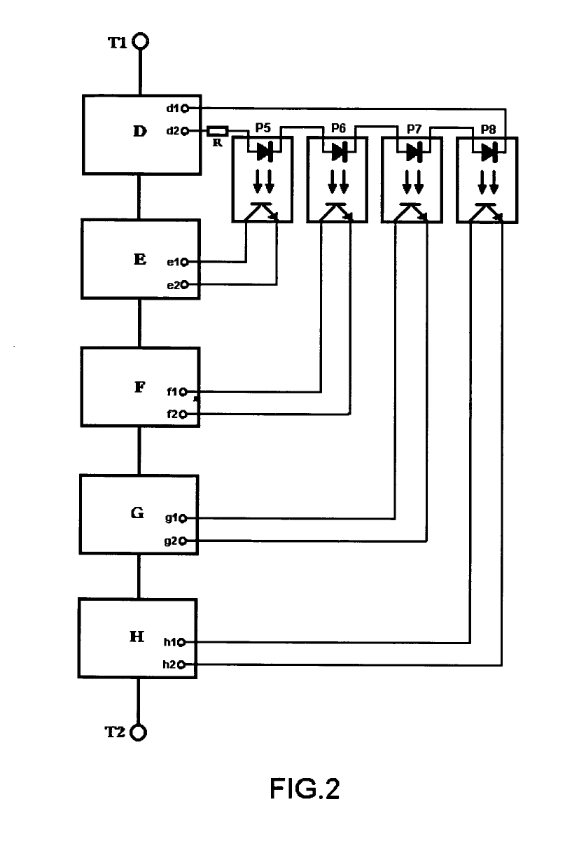

FIG. 2 is the first embodiment of the linkage apparatus with multi-units connected in series of this invention. In FIG. 2, there are five units, respectively D, E, F, G, and H, wherein, D is the mastering unit, the left are the controlled units; as each unit has only two external terminals, so when the five units are connected in series, a new two-wire circuit is realized that has only two external terminals (T1 and T2). In FIG. 2, there are four photocoupleres, respectively P5, P6, P7 and P8, terminals d1 and d2 are the output terminals of the internal control circuit of the mastering unit D, d1 and d2 are connected to the four LEDs in the four photocouplers P5, P6, P7 and P8 through current-limiting resistance R; terminals e1, f1, g1 and h1 are the suitable positive level nodes as compared with respectively four common reference nodes of the internal control circuits of the controlled units E, F, G and H; e2, f2, g2 and h2 are respectively the ON-OFF signal input terminals of the internal control circuits of the controlled units E, F, G and H; terminals e1 and e2, f1 and f2, g1 and g2, h1 and h2 are connected respectively to four photoconductive transistors in the four photocouplers P5, P6, P7 and P8.

As for the embodiment of FIG. 2, when the internal control circuit of the mastering unit D has the output signal, the MCBS module in the mastering unit D is ON, that is, the unit D is ON, and the output signal on the terminals d1 and d2 causes four LEDs in the photocouplers P5, P6, P7 and P8 lightened and four photoconductive transistors in the photocouplers P5, P6, P7 and P8 present a low resistance states; therefore the suitable positive level of the terminals e1, f1, g1 and h1 can reach the terminals e2, f2, g2 and h2 through corresponding photoconductive transistor, so that the ON-OFF signal input terminals e2, f2, g2, h2 of the internal control circuits of the controlled units E, F, G, H get suitable level input signals at the same time, and the MCBS modules in the controlled units E, F, G and H are ON, that is, the controlled units E, F, G and H are ON. Otherwise, when there is no output signal in the internal control circuit of the mastering unit D, the MCBS module in the mastering unit D is OFF, that is, unit D is OFF, and there is no output signal on the terminals d1 and d2, the four LEDs in the photocouplers P5, P6, P7 and P8 can not lighten, and four photoconductive transistors in photocouplers P5, P6, P7 and P8 present a high resistance state, and the suitable positive level of the terminals e1, f1, g1 and h1 can not reach the terminals e2, f2, g2 and h2 through corresponding photoconductive transistor, so that the ON-OFF signal input terminals of the internal control circuit of the controlled units E, F, G and H can not get the input signal, the MCBS modules in the controlled units E, F, G and H are OFF, that is, the controlled units E, F, G and H are OFF. Thus it can be seen, through signal transfer of the photocouplers P5, P6, P7 and P8, the five units D, E, F, G and H connected in series can have consistently-combined ON-OFF actions and thus complete the linkage of the multi-units connected in series, which is heightened the working voltage.

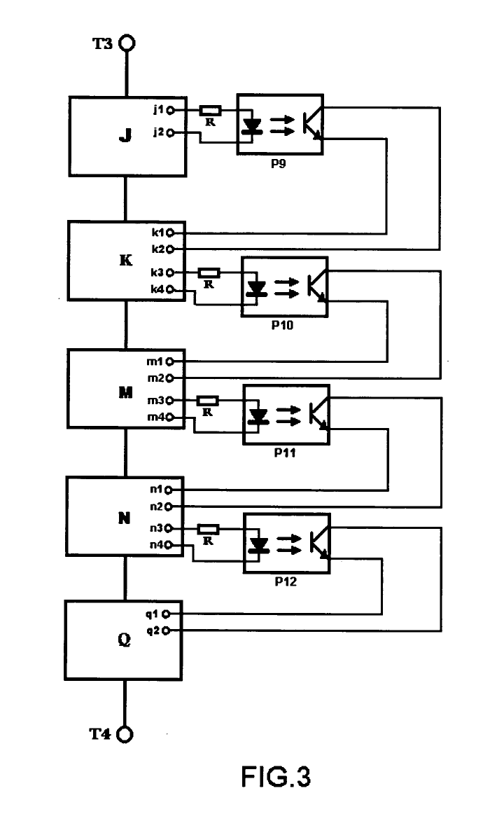

FIG. 3 is the second embodiment of the linkage apparatus with multi-units connected in series of this invention. In FIG. 3, there are five units, respectively J, K, M, N, and Q, wherein, J is the mastering unit, the left are the controlled units; as each unit has only two external terminals, so when the five units are connected in series, a new two-wire circuit is realized that has only two external terminals (T3 and T4). In FIG. 3, there are four photocouplers, respectively P9, P10, P11 and P12, terminals j1 and j2 are the output terminals of the internal control circuit of the mastering unit J, j1 and j2 are connected to the LED in the photocoupler P9 through current-limiting resistance R; terminals k3 and k4 are the output terminals of the internal control circuit of the controlled unit K, k3 and k4 are connected to the LED in the photocoupler P10 through current-limiting resistance R; terminals m3 and m4 are the output terminals of the internal control circuit of the controlled unit M, m3 and m4 are connected to the LED in the photocoupler P11 through current-limiting resistance R; terminals n3 and n4 are the output terminals of the internal control circuit of the controlled unit N, n3 and n4 are connected to the LED in the photocoupler P12 through current-limiting resistance R; terminals k2, m2, n2, q2 are the suitable positive level nodes as compared with respectively the common reference nodes of the internal control circuits of the controlled units K, M, N and Q; k1, m1, n1 and q1 are respectively the ON-OFF signal input terminals of the internal control circuits of the controlled units K, M, N and Q; terminals k1 and k2 are connected to the photoconductive transistor in the photocoupler P9, terminals m1 and m2 are connected to the photoconductive transistor in the photocoupler P10, terminals n1 and n2 are connected to the photoconductive transistor in the photocoupler P11, and terminals q1 and q2 are connected to the photoconductive transistor in the photocoupler P12.

As for the embodiment of FIG. 3, when the internal control circuit of the mastering unit J has the output signal and the MCBS module in the mastering unit J is ON, that is, unit J is ON, what's more, the output signal on the terminals j1 and j2 causes the LED in the photocoupler P9 lightened and the photoconductive transistor in the photocoupler P9 presents a low resistance state; and the suitable positive level of the terminal k2 can reach the terminal k1 through the photoconductive transistor in the photocoupler P9, so that the ON-OFF signal input terminal k1 of the internal control circuit of the controlled unit K have a suitable level signal, the output terminals k3, k4 of the internal control circuit of the controlled unit K has the output signal, the MCBS module in the controlled unit K is ON, that is, the controlled unit K is ON; what's more, the output signal on the terminals k3 and k4 causes the LED in the photocoupler P10 lightened this moment and the photoconductive transistor in the photocoupler P10 presents a low resistance state; and the suitable positive level of the terminal m2 can reach the terminal m1 through the photoconductive transistor in the photocoupler P10, so that the ON-OFF signal input terminal m1 of the internal control circuit of the controlled unit M get suitable level signal, the output terminals m3, m4 of the internal control circuit of the controlled unit M has the output signal, the MCBS module in the controlled unit M is ON, that is, the controlled unit M is ON; furthermore, the output signal on the terminals m3 and m4 causes the LED in the photocoupler P11 lightened this moment and the photoconductive transistor in the photocoupler P11 presents a low resistance state; and the suitable positive level of the terminal n2 can reach the terminal n1 through the photoconductive transistor in the photocoupler P11, so that the ON-OFF signal input terminal n1 of the internal control circuit of the controlled unit N get suitable level signal, the output terminals n3, n4 of the internal control circuit of the controlled unit N has the output signal, the MCBS module in the controlled unit N is ON, that is, the controlled unit N is ON; at the same time, the output signal on the terminals n3 and n4 causes the LED in the photocoupler P12 lightened and the photoconductive transistor in photocoupler P12 presents a low resistance state; and the suitable positive level of the terminal q2 can reach the terminal q1 through the photoconductive transistor in the photocoupler P12, so that the ON-OFF signal input terminal q1 of the internal control circuit of controlled unit Q have suitable level signal, the output terminals of the internal control circuit of the controlled unit Q have the output signal, the MCBS module in the controlled unit Q is ON, that is, the controlled unit N is ON; Otherwise, when there is no output signal in the internal control circuit of mastering unit J, and the MCBS module in the mastering unit J is OFF, that is, the unit J is OFF, and there is no output signal on the terminals j1 and j2, the LED in the photocoupler P9 can not lighten, and the photoconductive transistor in the photocoupler 9 presents a high resistance state, and the suitable positive level of the terminal k2 can not reach the terminal k1 through the photoconductive transistor in P9, so that the ON-OFF signal input terminal k1 of the internal control circuit of the controlled unit K can not get the signal, the MCBS module in the controlled unit K is OFF, that is, the controlled Unit K is OFF; and then the LED in the photocoupler P10 can not lighten, and the photoconductive transistor in the photocoupler 10 presents a high resistance state; and the suitable positive level of m2 can not reach m1 through the photoconductive transistor in P10, so that the ON-OFF signal input terminals m1 of the internal control circuit of the controlled unit M can not get the signal, the MCBS module in the controlled unit M is OFF, that is, the controlled unit M is OFF; in the same way, the LEDs in the photocouplers P11 and P12 can not lighten, and the photoconductive transistors in the photocoupler P11 and P12 present a high resistance state, the controlled units N and Q are both OFF. Thus it can be seen, through signal transfer of the photocouplers P9, P10, P11 and P12, the five units J, K, M, N and Q connected in series can have consistently-combined ON-OFF actions and thus complete the linkage of the multi-units connected in series, which is heightened the working voltage.

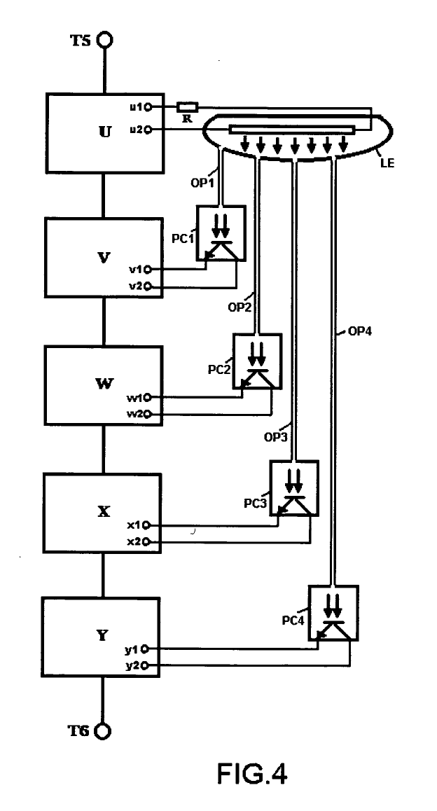

FIG. 4 is the third embodiment of the linkage apparatus with multi-units connected in series of this invention. In the FIG. 4, there are five units, respectively U, V, W, X and Y, wherein, U is the mastering unit, the left are controlled units; as each unit has only two external terminals, so when the five units are connected in series, a new two-wire circuit is realized that has only two external terminals (T5 and T6). In FIG. 4, terminals u1 and u2 are the output terminals of the internal control circuit of the mastering unit U, the terminals u1 and u2 are connected to the light emitting module LE through the current-limiting resistance R; OP1, OP2, OP3 and OP4 are four fibers; PC1, PC2, PC3 and PC2 are four photoconductive transistors; terminals v2, w2, x2, and y2 are the suitable positive level nodes as compared with respectively the common reference nodes of the internal control circuit of the controlled units V, W, X and Y; terminals v1, w1, x1 and y1 are respectively the ON-OFF signal input terminals of the internal control circuit of the controlled units V, W, X and Y; terminals v1 and v2 are connected to the photoconductive transistor PC1, terminals w1 and w2 are connected to the photoconductive transistor PC2, terminals x1 and x2 are connected to the photoconductive transistor PC3, while terminals y1 and y2 are connected to the photoconductive transistor PC4.

As for the embodiment of FIG. 4, when the internal control circuit of the mastering unit U has output signal and the MCBS module in the mastering unit U is ON, that is, unit U is ON, what's more, the output signal of the terminals u1 and u2 causes the light emitting module LE lightened, and the light shines four photoconductive transistors PC1, PC2, PC3 and PC4 through light propagation of four fibers OP1, OP2, OP3 and OP4, so that the four photoconductive transistors PC1, PC2, PC3 and PC4 present a low resistance states; and the suitable positive level of the terminals v2, w2, x2, and y2 can reach the terminals v1, w1, x1 and y1 through the four photoconductive transistors PC1, PC2, PC3 and PC4, therefore the ON-OFF signal input terminals v1, w1, x1, y1 of the internal control circuits of controlled units V, W, X and Y can get suitable level input signal, the MCBS modules in the controlled units V, W, X and Y are ON, that is, the controlled units V, W, X and Y are ON; otherwise, when the internal control circuit of the mastering unit U has no output signal and the MCBS module in the mastering unit U is OFF, that is, unit U is OFF, what's more, there is no output signal on the terminals u1 and u2, the light emitting module LE can not lighten and the four photoconductive transistors PC1, PC2, PC3 and PC4 present a high resistance states; and the suitable positive level of the terminals v2, w2, x2, and y2 can not reach v1, w1, x1 and y1 through the four photoconductive transistors PC1, PC2, PC3 and PC4, so that the ON-OFF signal input terminals v1, w1, x1, y1 of the internal control circuits of the controlled units V, W, X and Y can not get the input signal, the MCBS modules in the controlled units V, W, X and Y are OFF, that is, the controlled units V, W, X and Y are OFF. Thus it can be seen, through signal transfer of the light emitting module LE and four fibers OP1, OP2, OP3, OP4 and the four photoconductive transistors PC1, PC2, PC3, PC4, the five units J, K, M, N and Q connected in series can have consistently-combined ON-OFF actions and thus complete the linkage of the multi-units connected in series, which is heightened the working voltage.

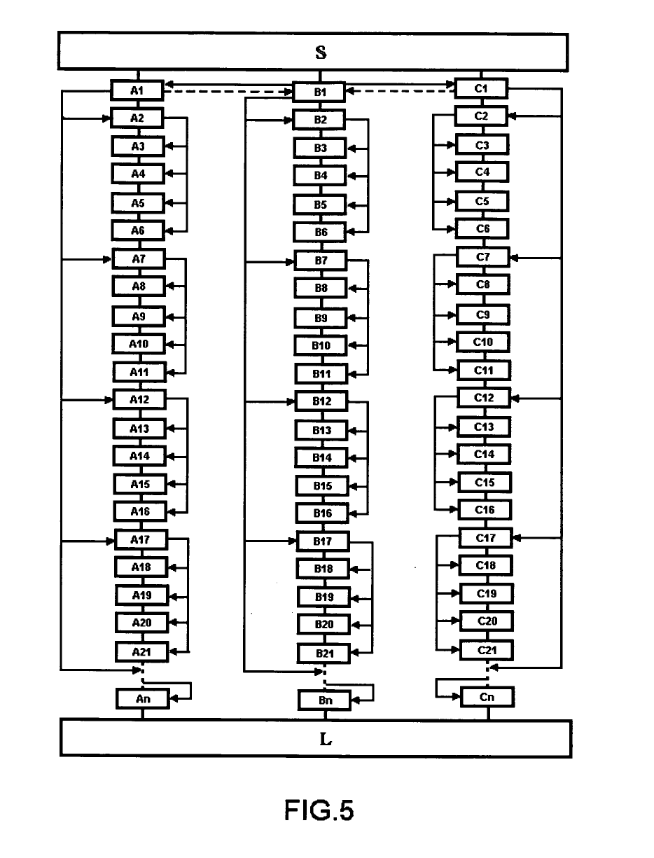

FIG. 5 is the first embodiment of three-phase high voltage multi-units linkage apparatus of this invention. In FIG. 5, due to the large number of the units and their related devices involved, simplified diagram will be adopted here for illustration. In FIG. 5, A1, A2, A3 . . . to An, B1, B2, B3 . . . to Bn, C1, C2, C3 . . . to Cn are respectively made up of n units into the three linkage apparatuses with multi-units connected in series, S is the three-phase power supply, L is the three-phase load. As each of the three linkage apparatuses is a two-wire circuit apparatus which has only two external terminals, it is the same with the embodiment of FIG. 1, the six external terminals of the three linkage apparatuses are respectively connected to the three-phase power supply and three-phase load. As shown in the FIG. 5, the solid line and the arrow indicate the route and direction which transmit ON-OFF control signal through photoelectric coupling, while the dotted line and the arrow indicate the route and direction which transmit the short-circuit fault signal through photoelectric coupling. In FIG. 5, B1 is the mastering unit, others are the controlled units. The transmission of the ON-OFF control signal from B1 to A1 and B1 to C1, and the transmission of the short-circuit fault signal from A1 to B1 and C1 to B1, they are the same with the embodiment of FIG. 1. The transmission of the ON-OFF control signal from B1 to B2, B7, B12, B17, etc. is the same with the embodiment of FIG. 4, this is a way using the non-metal fibers to transmit signals between units with many units in between will not cause generally voltage breakdown. The transmission of the ON-OFF control signal from A1 to A2, A7, A12, A17, etc. and C1 to C2, C7, C12, C17, etc. also adopts the same method as used in the embodiment of FIG. 4. The left transmission of the ON-OFF control signals, for example, from A2 to A3, A4, A5, etc., from B7 to B8, B9, B10, B11, etc., from C17 to C18, C19, C20, C21, etc., adopts the same method as used in the embodiment of FIG. 2.

As for the embodiment of FIG. 5, the transmission of the ON-OFF control signal starts from the mastering unit B, reaches to all the other units along the solid line and arrow level by level to several levels, thereby consistently-combined ON-OFF actions are realized. When there is short-circuit fault on the external circuit of A1 or C1, the short-circuit fault signal can be transmitted from A1 or C1 to B1, as B1 itself has short-circuit protection function, thus when any a phase external circuit of the three-phase external circuits has short-circuit fault, all the units can be consistently-combined “OFF”, therefore, this embodiment has the three-phase high voltage solid-state short-circuit protection function.

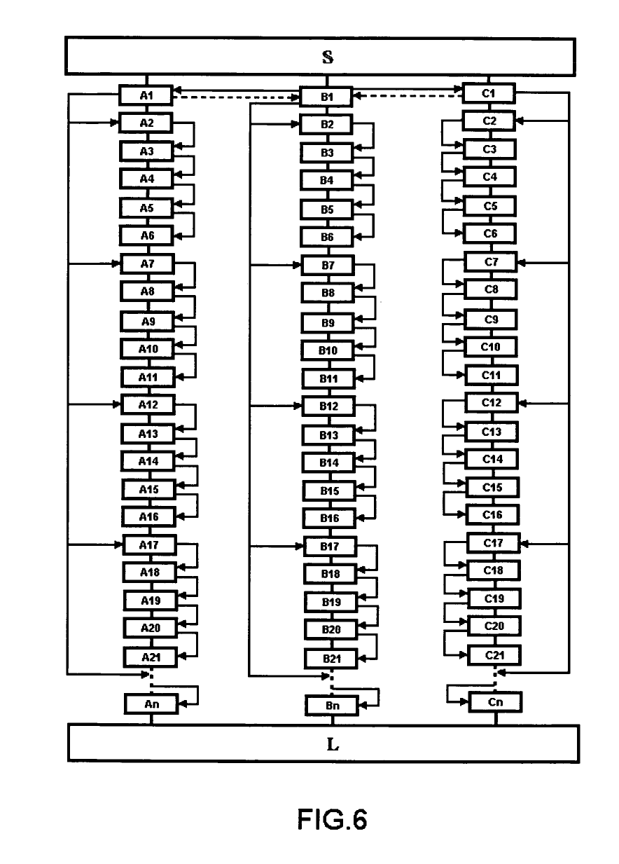

FIG. 6 is the second embodiment of three-phase high voltage multi-units linkage apparatus of this invention. There is only one difference of this embodiment from the embodiment of FIG. 5, that is, the transmission of the ON-OFF control signal of the last level, for example, from A2 to A3, A4, A5, etc. from B7 to B8, B9, B10, B11, etc. from C17 to C18, C19, C20, C21, etc, adopts the same method as used in the embodiment of FIG. 3. As the signal is transmitted between two adjacent units, the voltage breakdown of the photocoupler will not occur. As for the others of the FIG. 6, it is the same with that of the FIG. 5 please refer to FIG. 5.

What is claimed is:

1. A linkage apparatus of alternating-current two-wire solid-state switches is used for the three-phase circuit comprising:
one mastering alternating-current two-wire solid-state switch and two controlled alternating-current two-wire solid-state switches, and optical coupling complexes;
means for connecting one external terminal of a pair of external terminals on said mastering alternating-current two-wire solid-state switch and another two external terminals of two pairs of external terminals on the said two controlled alternating-current two-wire solid-state switches to the three-phase power supply, and connecting another external terminal of a pair of external terminals on said mastering alternating-current two-wire solid-state switch and other two external terminals of two pairs of external terminals on said two controlled alternating-current two-wire solid-state switches to the three-phase load;
said optical coupling complex includes a light emitting device and a photoconducting device; said mastering alternating-current two-wire solid-state switch to transfer ON-OFF control signal to each said controlled alternating-current two-wire solid-state switch must pass through said optical coupling complex in the optical isolation; said two controlled alternating-current two-wire solid-state switches to transfer the short-circuit fault signal to said mastering alternating-current two-wire solid-state switch must pass through the said optical coupling complexes in the optical isolation;
means for connecting the ON-OFF control signal output terminals of the internal control circuit of said mastering alternating-current two-wire solid-state switch to corresponding light emitting device of said optical coupling complex, and connecting the ON-OFF control signal input terminals of the internal control circuit of said controlled alternating-current two-wire solid-state switch to corresponding photoconducting device of said optical coupling complex means the ON-OFF control output signal of said mastering alternating-current two-wire solid-state switch can be transferred to each said controlled alternating-current two-wire solid-state switch through corresponding optical coupling complex at the same time, therefore all alternating-current two-wire solid-state switches have consistently-combined ON-OFF actions;
means for connecting the short-circuit fault signal output terminals of the internal control circuit of said controlled alternating-current two-wire solid-state switch to corresponding light emitting device of said optical coupling complex, and connecting the short-circuit fault signal input terminal of the internal control circuit of said mastering alternating-current two-wire solid-state switch to corresponding photoconducting device of said optical coupling complex means the short-circuit fault signal which is generated by the short-circuit fault happening in the external circuits which are connected to any one of said controlled alternating-current two-wire solid-state switches can transfer to said mastering alternating-current two-wire solid-state switch through corresponding optical coupling complex, therefore all alternating-current two-wire solid-state switches have consistently-combined OFF action when happening the short-circuit fault in the external circuits which are connected to any one of said alternating-current two-wire solid-state switches.

2. A linkage apparatus of many alternating-current two-wire solid-state switches which are connected in series comprising:
one mastering alternating-current two-wire solid-state switch and many controlled alternating-current two-wire solid-state switches, and optical coupling complexes;
means for connecting the two external terminals of said all alternating-current two-wire solid-state switches into series configuration means the linkage apparatus has only two external terminals with many alternating-current two-wire solid-state switches;
said optical coupling complex includes a light emitting device and a photoconducting device; said mastering alternating-current two-wire solid-state switch to transfer ON-OFF control signal to each said controlled alternating-current two-wire solid-state switch must pass through the said optical coupling complex in the optical isolation;
means for connecting the ON-OFF control signal output terminals of the internal control circuit of said mastering alternating-current two-wire solid-state switch to corresponding light emitting device of said optical coupling complex and connecting the ON-OFF control signal input terminals of the internal control circuit of said controlled alternating-current two-wire solid-state switches to corresponding photoconducting device of said optical coupling complex means the ON-OFF control output signal of said mastering alternating-current two-wire solid-state switch can transfer to each said controlled alternating-current two-wire solid-state switch through corresponding optical coupling complex at the same time, therefore all alternating-current two-wire solid-state switches have consistently-combined ON-OFF actions.

3. A linkage apparatus of many alternating-current two-wire solid-state switches which are connected in series comprising:
one mastering alternating-current two-wire solid-state switch and many controlled alternating-current two-wire solid-state switches, and a light emitting module, many optical path spreading devices and many photoconducting devices;
means for connecting the two external terminals of said all alternating-current two-wire solid-state into series configuration means the linkage apparatus has only two external terminals with many alternating-current two-wire solid-state switches;
said mastering alternating-current two-wire solid-state switch to transfer ON-OFF control signal to each said controlled alternating-current two-wire solid-state switch must pass through said optical path spreading device and said photoconducting device in the optical isolation;
means for connecting the ON-OFF signal output terminals of the internal control circuit of said mastering alternating-current two-wire solid-state switch to said light emitting module and connecting the ON-OFF signal input terminals of the internal control circuit of the said controlled alternating-current two-wire solid-state switches to corresponding photoconductive device means the ON-OFF control output signal of said mastering alternating-current two-wire solid-state switch can transfer to each said controlled alternating-current two-wire solid-state switch through said light emitting module, corresponding optical path spreading device and corresponding photoconducting device at the same time, therefore all alternating-current two-wire solid-state switches have consistently-combined ON-OFF actions.

4. A linkage apparatus of many alternating-current two-wire solid-state switches which are connected in series comprising:
one mastering alternating-current two-wire solid-state switch and many controlled alternating-current two-wire solid-state switches, and optical coupling complexes;
means for connecting two external terminals of said all alternating-current two-wire solid-state switches into series configuration means the linkage apparatus having only two external terminals with many alternating-current two-wire solid-state switches;
said optical coupling complex includes a light emitting device and a photoconducting device means the ON-OFF control signal between all adjacent said alternating-current two-wire solid-state switches to be transferred must pass through the said optical coupling complex in the optical isolation, therefore the ON-OFF control output signal of said mastering alternating-current two-wire solid-state switch can be transferred between adjacent alternating-current two-wire solid-state switches one by one until to a controlled alternating-current two-wire solid-state switch which is on the edge through said optical coupling complexes;
means for connecting the ON-OFF control signal output terminals of the internal control circuit of said mastering alternating-current two-wire solid-state switch to corresponding light emitting device of said optical coupling complex and connecting the ON-OFF control signal input terminals of the internal control circuit of said controlled alternating-current two-wire solid-state switch on the edge to corresponding photoconducting device of the said optical coupling complex, and connecting the ON-OFF control signal output terminals of the internal control circuit of remaining said controlled alternating-current two-wire solid-state switches to corresponding light emitting device of the said optical coupling complex and connecting their the ON-OFF control signal input terminals to corresponding photoconducting device of said optical coupling complex means the ON-OFF control output signal of the mastering alternating-current two-wire solid-state switch can be transferred to every said controlled alternating-current two-wire solid-state switch one by one according to adjacent relations through corresponding optical coupling complex, therefore all alternating-current two-wire solid-state switches have consistently-combined ON-OFF action.

5. The linkage apparatus of claim 1 wherein said mastering alternating-current two-wire solid-state switch and each said controlled alternating-current two-wire solid-state switch have only two external terminals; said mastering alternating-current two-wire solid-state switch and each said controlled alternating-current two-wire solid-state switch include a main circuit bidirectional switching module, a secondary winding of the current mutual inductor, a bridge rectifying circuit, a control circuit and a suitable positive level node as compared with the common reference node of the control circuit; said mastering alternating-current two-wire solid-state switch has yet short-circuit protection function.

6. The linkage apparatus of claim 1 wherein the linkage apparatus is a three-phase alternating-current solid-sate breaker.

7. The linkage apparatus of claim 1 wherein the linkage apparatus is a three-phase alternating-current solid-state short-circuit protector.

8. The linkage apparatus of claim 2 wherein said mastering alternating-current two-wire solid-state switch and each said controlled alternating-current two-wire solid-state switch have only two external terminals; said mastering alternating-current two-wire solid-state switch and each said controlled alternating-current two-wire solid-state switch include a main circuit bidirectional switching module, a control circuit and a suitable positive level node as compared with the common reference node of the control circuit.

9. The linkage apparatus of claim 3 wherein said mastering alternating-current two-wire solid-state switch and each said controlled alternating-current two-wire solid-state switch have only two external terminals; said mastering alternating-current two-wire solid-state switch and each said controlled alternating-current two-wire solid-state switch include a main circuit bidirectional switching module, a control circuit and a suitable positive level node as compared with the common reference node of the control circuit.

10. The linkage apparatus of claim 3 wherein said many optical path spreading devices involving many fibers.

11. The linkage apparatus of claim 4 wherein said mastering alternating-current two-wire solid-state switch and each said controlled alternating-current two-wire solid-state switch have only two external terminals; said mastering alternating-current two-wire solid-state switch and each said controlled alternating-current two-wire solid-state switch include a main circuit bidirectional switching module, a control circuit and a suitable positive level node as compared with the common reference node of the control circuit.
